(19) United States
(12) Patent Application Publication
(10) Pub. No.: US 2007/0132073 A1
(43) Pub. Date: Jun. 14, 2007

(54) DEVICE AND METHOD FOR ASSEMBLING A TOP AND BOTTOM EXPOSED PACKAGED SEMICONDUCTOR

(76) Inventors: Toong Teik Tiong, Penang (MY); Maria Cristina B. Estacio, Cebu City (PH); David Chong Sook Lim, Penang (MY)

Correspondence Address: HISCOCK & BARCLAY, LLP, 2000 HSBC PLAZA, 100 Chestnut Street, ROCHESTER, NY, 14604-2404, US

(21) Appl. No.: 11/608,626

(22) Filed: Dec. 8, 2006

Related U.S. Application Data
(60) Provisional application No. 60/749,145, filed on Dec. 9, 2005.

(51) Int. Cl. H01L 21/00; H01L 23/495

(52) U.S. Cl. 257/666; 438/123

(57) ABSTRACT

A packaged semiconductor device includes a two piece lead assembly having vertically separated top and bottom lead frames. A semiconductor die is between the two lead frames and makes electrical and thermal contact to the two lead frames. The lower lead frame is generally flat while the upper lead frame has a flat top surface and downward extensions that fall on two opposite sides of the lower lead frame and that end in flanges that have bottom surfaces that are coplanar with the bottom surface of the bottom lead frame. When the assembly is molded, the top surface of the top lead frame and the bottom surfaces of the flanges and the bottom lead frame are exposed to allow electrical contact to the semiconductor die and to provide thermal conductive paths to dissipate heat developed in the semiconductor die.

### CROSS-REFERENCE TO RELATED APPLICATIONS

This application claims priority from U.S. Provisional Patent Application Ser. No. 60/749,145, filed on Dec. 9, 2006, which application is hereby incorporated by reference.

### FIELD OF THE INVENTION

This invention relates to a packaged semiconductor device and a method for making the same.

### BACKGROUND OF THE INVENTION

Packaged power semiconductor devices generally require a package that efficiently conducts heat away from the semiconductor device. It is known to mold the packaged semiconductor with a heat sink, or clip, to dissipate the heat generated by the semiconductor device. However, accurately placing the prior art clips without tilting the clips can be a problem in the manufacture of these packages.

Another problem associated with manufacturing molded packaged semiconductors is maintaining a uniform final package thickness for the devices. For example, in some prior art devices the stacked height of a device with a top exposed drain clip is dependent on the height of a solder connection between the clip and the die bonding frame. As compared to a screen-printing solder process, solder volume cannot be dispensed consistently to maintain thickness uniformity between devices.

Still another problem associated with manufacturing molded packaged semiconductor devices is managing the mechanical stress during the molding process. For example, in a device with a top exposed drain clip, the vertical compressive stress will concentrate on the drain clip and be further translated along a vertical axis to the solder connection, and down along the semiconductor die. Stresses developed at the time of molding may cause problems both in the structural and functional performance of the devices. Thus, a device that minimizes compression stress to the semiconductor die is desirable.

### SUMMARY OF THE INVENTION

This invention comprises, in one form thereof, a method of packaging a semiconductor device including providing a first lead frame having electrically isolated first and second leads, attaching a semiconductor device with solderable connections to the first lead frame, and placing a second lead frame over the semiconductor device and the first lead frame, the second lead frame having extension legs situated on opposite sides of the second lead frame and extending downward from a top of the second lead frame toward the first lead frame and terminating in two flanges that are parallel with the top of the second lead frame, such that the bottoms of the flanges are coplanar with the bottom of the first lead frame. The method includes soldering an underside of the top of the second lead frame to the die, and molding over the first and second lead frames and the die with an encapsulating material, while leaving exposed the top of the second lead frame, the bottom of the flanges, and the bottom of the first lead frame.

This invention also comprises, in one form thereof, a packaged semiconductor device having a first lead frame with electrically isolated first and second leads, a semiconductor device with solderable connections attached to the first lead frame, and a second lead frame soldered to the semiconductor device and lying over the semiconductor device and the first lead frame, the second lead frame having extension legs situated on opposite sides of the second lead frame and extending downward from a top of the second lead frame toward the first lead frame and terminating in two flanges that are parallel with the top of the second lead frame, such that the bottoms of the flanges are coplanar with a bottom of the first lead frame.

An advantage of the present invention is that the top frame has a top-exposed drain clip to remove heat from the device, and includes leg extensions that carry drain leads to a same plane as the source and gate leads.

### BRIEF DESCRIPTION OF THE DRAWINGS

The above-mentioned and other features and advantages of this invention, and the manner of attaining them, will become apparent and be better understood by reference to the following description of the various embodiments of the invention in conjunction with the accompanying drawings, wherein:

FIGS. 1A, 1B, 1C, 1D, 1F, and 1F are cross-sectional views taken along line 1A-F-1A-F in FIG. 4 of components that are assembled in a series of steps in a manufacturing method for forming a packaged semiconductor device in accordance with the present invention;

FIG. 2 is a top isometric view of a two piece lead frame assembly in accordance with the present invention;

FIG. 3 is a top isometric view of a packaged semiconductor shown in FIG. 1F;

FIG. 4 is a bottom view of the packaged semiconductor device shown in FIG. 1F; and

FIG. 5 is a cross-sectional view of a modification of one of the devices shown in FIG. 1C.

It will be appreciated that for purposes of clarity, and where deemed appropriate, reference numeral have been repeated in the figures to indicate corresponding features. Also, the relative size of various objects in the drawings has in some cases been distorted to more clearly show the invention.

### DETAILED DESCRIPTION

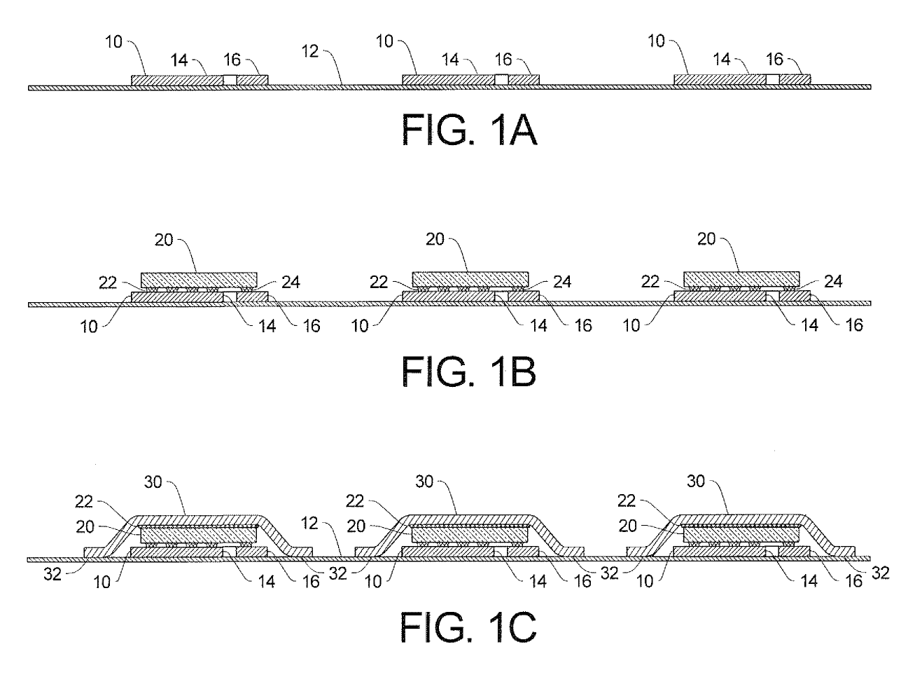

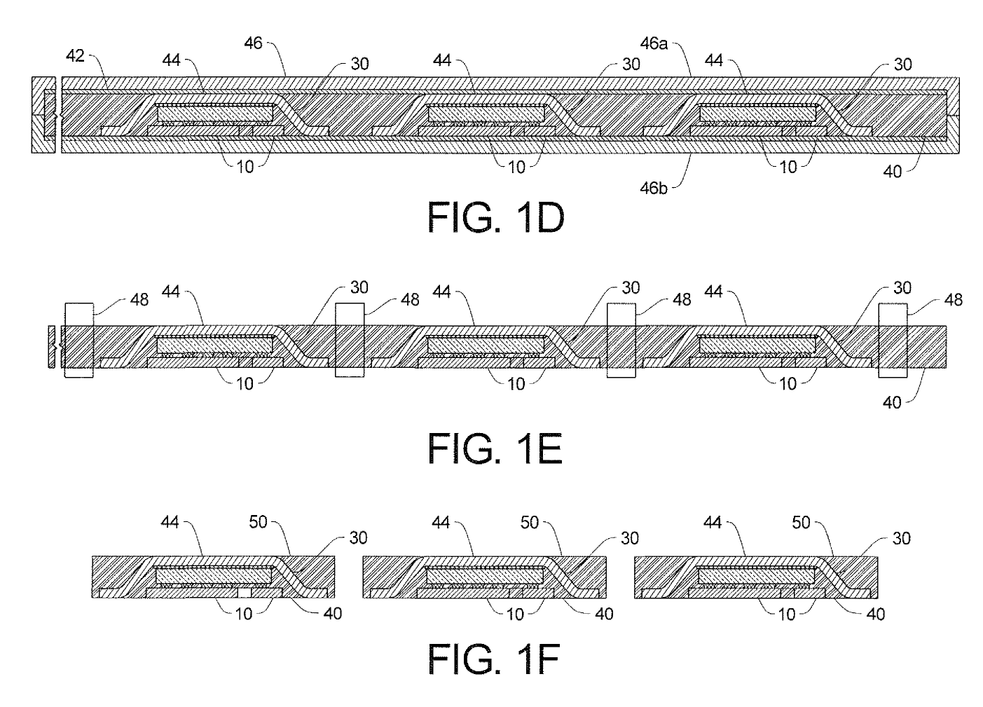

Referring to FIGS. 1A-F, there is shown a series of manufacturing steps associated with a method of creating a packaged semiconductor device in accordance with the present invention. In one embodiment, bottom lead frames 10 are laminated with tape 12 as shown in FIG. 1A. Although only a single strip of individual devices is shown in FIGS. 1A-F, the manufacturing process may fabricate the devices either in a strip or in a matrix. The bottom lead frame 10 can be constructed as a layer of rolled or electro-deposited and plated copper or similar electrically conductive material. The bottom lead frame 10 includes electrically isolated source leads 14 and gate leads 16.

As shown in FIG. 1B a flip-chip die 20, which may be a power MOSFET, with solder ball contacts is mounted on the bottom lead frame 10 and reflow soldered to form the solder connections 22 and 24 between the source leads 14 and the gate leads 16, respectively. The solder contacts may be formed using Under Bump Metal (UMB) or using copper studs.

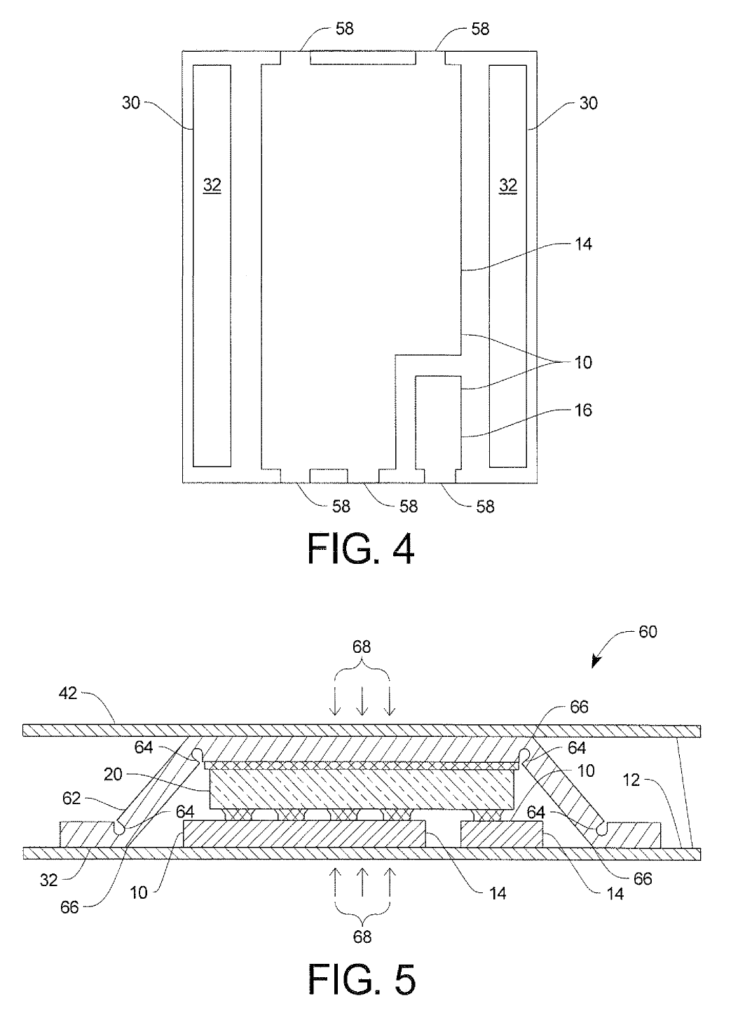

Referring now to FIG. 1C, after a solder paste 22 is printed or dispensed onto the back of the die 20 and a top lead frame 30 is placed over the bottom lead frame 10 and die 20, a second reflow solder operation solders the top lead frame 30 to the die 20. In one embodiment, the top lead frame 30 is copper based. The top lead frame 30, which may be connected to the drain of the die 20, is vertically positioned to contact the tape 12 with the exposed leads 32 (shown in FIG. 4) of the completed device on opposite sides of the bottom lead frame 10. As mentioned above, the bottom lead frame 10 and the top lead frame 30 each may be formed as separate strips or matrices and assembled using guide holes and alignment pins to accurately align the bottom and top lead frames. U.S. Pat. No. 6,762,067 describes such a procedure.

FIG. 1D shows the state of the processing after a molding operation performed to the strip (or matrix) of the devices shown in FIG. 1C. Prior to the injection of a molding compound 40, a film 42 for film assist molding is placed across the tops 44 of the top lead frames 30. Alternatively, a tape like tape 12 may be applied to the tops 44 of the top lead frames 30 prior to the joining of the bottom lead frames 10 and the top lead frames 30. After the film 42 is in place, the assembly is placed into a mold press 46, having a top chase 46a and a bottom chase 46b, and a molding compound 40 is injected into the molding press. The molding compound may be a non-conductive polymer encapsulation material, such as an epoxy.

FIG. 1E has rectangles 48 indicating where the assembly is to be sawn, and FIG. 1F shows the completed sawn devices 50.

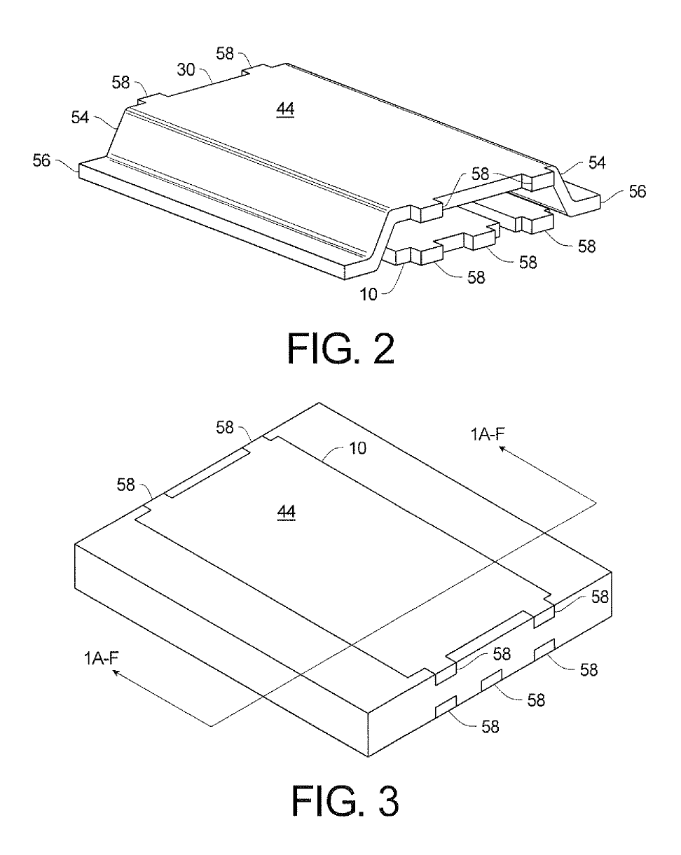

FIG. 2 is a top isometric view showing the relative positions of the top lead frame 30 and the bottom lead frame 10 in the completed device 50. The top or clip 44 of the top lead frame 30 is not covered by molding material 40 in the completed device 50 and thus is a heat sink that allows an additional heat sink to mounted directly onto the top 44. The top lead frame 30 also includes extension legs 54 on opposite sides of the top lead frame 30 extending downward from the exposed top 44 to two flanges 56 that are parallel with the top 44. The extension legs 54 provide a vertical upset from the bottom lead frame 10 and determines the height of the completed device 50. Tie bars 58 are the reminents of the tie bars used to hold the top and bottom lead frames in place in their respective strip or matrix assemblies prior to the sawing operation described above with respect to FIG. 1E.

FIG. 3 is a top isometric view, and FIG. 4 is a bottom view of the completed device 50 which show the exposed portions of the top lead frame 30 and the bottom lead frame 10.

FIG. 5 is a cross-sectional view 60 of one of the devices shown in FIG. 1C which has been modified according to another embodiment of the invention. In FIG. 5 the top lead frame 30 shown in the previous figures has been replaced by a modified top lead frame 62. The top lead frame 62 has cutouts 64 at the inside of each bend in the top lead frame 62 allowing the outside corners 66 to be more pointed than the bent outside corners of the top lead frame 30. As a result the area of the exposed surfaces of the top lead frame 62 on the completed device is larger than with the top lead frame 30 while still retaining the same device outside dimensions and accommodating the same die size.

The support of the top lead frames 30, 62 on the bottom tape 12 means that the package height is determined by the height of the top lead frames 30, 62. Moreover, during the molding operation the molding press exerts a vertical compressing stress on the device, as indicate by the arrows 68 in FIG. 5, to prevent the molding material from flowing between the tape 12 and the bottom lead frame 10 and the bottom surfaces 32 of the top lead frame 30 and from flowing between the film 42 and the top surface 44 of the top lead frame 30. The top lead frames 30, 62 provide the needed support to absorb most of this stress such that the die 20 is not subjected to the vertical stress which could damage the die 20 during the molding process, and also to virtually eliminate any decrease of the height of the device during the molding operation.

While the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

Therefore, it is intended that the invention not be limited to the particular embodiments disclosed as the best mode contemplated for carrying out this invention, but that the invention will include all embodiments falling within the scope and spirit of the appended claims.

We claim:

1. A method of packaging a semiconductor device, comprising the steps of:
(a) providing a first lead frame having electrically isolated first and second leads;
(b) attaching a semiconductor device with solderable connections to said first lead frame;
(c) placing a second lead frame over said die and said first lead frame, said second lead frame having extension legs situated on opposite sides of said second lead frame and extending downward from a top of said second lead frame toward said first lead frame and terminating in two flanges that are parallel with said top of said second lead frame, such that the bottoms of said flanges are coplanar with a bottom of said first lead frame;
(d) soldering an underside of said top of said second lead frame to said semiconductor device; and
(e) molding over said first and second lead frames and said die with an encapsulating material, while leaving exposed said top of said second lead frame, said bottom of said flanges, and said bottom of said first lead frame.

2. The method of claim 1 wherein said first lead frame comprises copper.

3. The method of claim 1 wherein said solderable connections comprises a plurality of conductive bumps.

4. The method of claim 3 wherein said conductive bumps comprise solderable material.

5. The method of claim 1 wherein a solder paste is applied to said semiconductor device before the placement of said second lead frame, and after said second lead frame is in place a solder reflow operation is performed.

6. The method of claim 1 wherein said second lead frame comprises copper.

7. The method of claim 1 wherein said second lead frame determines the overall height of said individual packaged devices.

8. The method of claim 1 wherein molding step comprises applying a non-conductive polymer encapsulation material.

9. The method of claim 8 wherein said non-conductive polymer encapsulation material is an epoxy.

10. The method of claim 1 wherein grooves are formed in said second lead frame at locations where said second lead frame will form inside bends.

11. A packaged semiconductor device comprising:
(a) a first lead frame having electrically isolated first and second leads;
(b) a semiconductor device with solderable connections attached to said first lead frame; and
(c) a second lead frame soldered to said die and lying over said semiconductor device and said first lead frame, said second lead frame having extension legs situated on opposite sides of said second lead frame and extending downward from a top of said second lead frame toward said first lead frame and terminating in two flanges that are parallel with said top of said second lead frame, such that the bottoms of said flanges are coplanar with a bottom of said first lead frame.

12. The device of claim 11 wherein said die and portions of said first and second lead frames are in contact with a molding compound.

13. The device of claim 11 wherein said solderable connections comprises a plurality of conductive bumps.

14. The device of claim 13 wherein said conductive bumps comprises solderable material.

15. The device of claim 11 wherein said second lead frame comprises copper.

16. The device of claim 11 wherein said second lead frame determines the overall height of said individual packaged devices.

17. The device of claim 12 wherein said molding compound comprises a non-conductive polymer encapsulation material.

18. The device of claim 17 wherein said non-conductive polymer encapsulation material is an epoxy.

19. The device of claim 11 wherein inside bends of said second lead frame contain grooves.

20. A packaged semiconductor device comprising:
(a) a power MOSFET semiconductor device with a drain terminal on one surface and source and gate terminals on an opposite surface;
(b) a bottom lead frame with exposed, electrically isolated source and gate lands;
(c) a top lead frame with a top surface and legs extending from the heat sink toward the bottom lead frame ending in flanges that are parallel with said top surface, the bottoms of said flanges being coplanar with the bottom of said bottom lead frame; and
(d) encapsulating material for protecting the die and configured to expose the top and bottom surfaces of the top lead frame and the bottom of said first lead frame.

21. The packaged semiconductor device of claim 20 wherein the top lead frame is in electrical and thermal contact with the drain terminal of said semiconductor device.

22. The packaged semiconductor device of claim 20 wherein said legs are disposed on opposite sides of said top and bottom lead frames.
